(19) United States
(12) Patent Application Publication
(10) Pub. No.: US 2026/0254471 A1
(43) Pub. Date: Aug. 27, 2026

(54) SYNCHRONIZATION ARCHITECTURE FOR INTER-CHIPLET COMMUNICATION WITHIN THREE-DIMENSIONAL INTEGRATED CIRCUIT

(71) Applicant: TAIWAN SEMICONDUCTOR MANUFACTURING COMPANY LTD., HSINCHU (TW)

(72) Inventors: HSIN-HUNG KUO, HSINCHU CITY (TW); MU-SHAN LIN, HSINCHU CITY (TW)

(21) Appl. No.: 19/062,079

(22) Filed: Feb. 25, 2025

(51) Int. Cl. H04B 1/16; H03L 7/08

(52) U.S. Cl. CPC H04B 1/1638; H03L 7/0807; H04B 1/1607

(57) ABSTRACT

The present disclosure provides a receiver device, which includes a deserializer and a dynamic reset generation circuit. The deserializer includes a first stage, a clock divider, and a second stage. The first stage converts an input serial data signal to a first partial serial data signal and a second partial serial data signal using a first clock signal set. The clock divider divides the first clock signal set by a clock division ratio to generate a second clock signal set. The second stage demultiplexes the first and second partial serial data signals to generate first and a second half parallel data signals using the second clock signal set, respectively. The dynamic reset generation circuit de-asserts a reset signal of the clock divider in response to a valid frame and a first clock signal within the first clock signal set.

### BACKGROUND

In the realm of advanced high-performance computing (HPC) development, the heterogeneous system-in-package (SiP) approach utilizing chiplets is increasingly being adopted due to its cost-effectiveness and improved yield. The Universal Chiplet Interconnect Express (UCIe) interface serves as the clock-forwarded parallel interface facilitating inter-chiplet communication within three-dimensional integrated circuits (3DICs). Within the UCIe interface, a serializer/deserializer (SerDes) circuit is employed to convert parallel data into serial data and vice versa, thereby enabling efficient data transmission over high-speed links. In existing SerDes circuits, the demultiplexing ratio is typically fixed to maintain simplicity in the gearing circuitry for high-speed operations. However, increasing the demultiplexing ratio could enhance the total bandwidth of the UCIe interface, although it may result in imbalanced high/low byte data traffic.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features can be arbitrarily increased or reduced for clarity of discussion.

FIG. 1 is a block diagram of a communication system in accordance with some embodiments of the present disclosure.

FIG. 2 is a waveform diagram illustrating a valid framing scheme in an inter-die communication protocol in accordance with some embodiments of the present disclosure.

FIG. 3 is a waveform diagram illustrating a clock gating scheme in the inter-die communication protocol in accordance with some embodiments of the present disclosure.

FIG. 4 is a block diagram of a receiver compatible with the first inter-die communication protocol in accordance with some embodiments of the present disclosure.

FIG. 5 is a detailed block diagram of the dynamic reset generation circuit 420 in accordance with the embodiment of FIG. 4.

FIG. 6 is a waveform diagram of various signal within the receiver in accordance with the embodiment of FIG. 5.

FIG. 7 is another waveform diagram of various signal within the receiver in accordance with the embodiment of FIG. 5.

FIG. 8 is a diagram illustrating waveforms of various signal and the statuses of data buffers within the receiver in accordance with the embodiment of FIG. 5.

FIG. 9 is a flowchart of a method for operating a receiver device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, it will be understood that when an element is referred to as being “connected to” or “coupled to” another element, it can be directly connected to or coupled to the other element, or intervening elements can be present.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device can be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

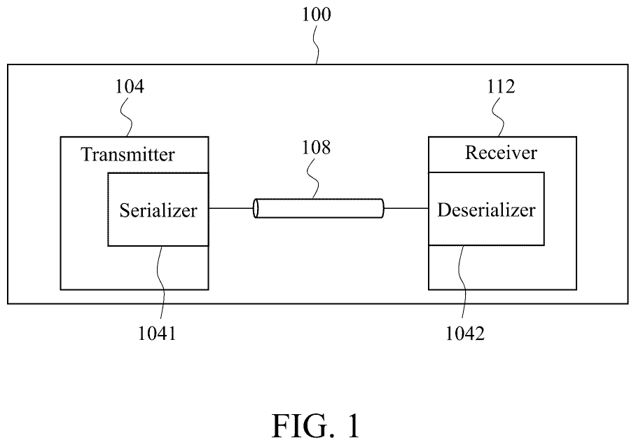

FIG. 1 is a block diagram of a communication system in accordance with some embodiments of the present disclosure.

In some embodiments, the communication system 100 may include a transmitter 104 and a receiver 112. The transmitter 104 is communicatively coupled to the receiver 112 via a communication channel 108. The transmitter 104 is configured to send one or more signals to the receiver 112 through the communication channel 108. The communication channel 108 may be a physical transmission medium, such as a backplane, drive head in a magnetic recording system, copper cables, optical fibers, one or more coaxial cables, and/or wire, or the communication channel 108 may include a one or more radio frequency (RF) channels. Although described herein as being utilized in a communication system 100, examples of the present disclosure are not so limited, and some examples might be employed in alternative communications systems utilizing a transmitter and a receiver communicating over a communication channel. Moreover, it is understood that each “bit” of a signal has a corresponding logic value and that various signals described herein may utilize multi-bit data symbols based on various data encoding schemes, such as pulse amplitude modulation (e.g., PAM-4).

In some embodiments, the transmitter 104 may include a serializer 1041 configured to convert a plurality of bits of a parallel input data signal to a serial data signal. Additionally, the receiver 112 may include a deserializer 1042 configured to convert a serial data signal to a parallel data signal. For example, the serializer 1041 may send the serial data signal, which is converted from a parallel input data signal, to the deserializer 1042 through the communication channel 108. Accordingly, the communication system 100 can also be regarded as a SerDes (serializer/deserializer) communication system.

In some embodiments, the transmitter 104 and the receiver 112 may be disposed on first die and a second die (both not shown), respectively, while the communication channel 108 may be a physical data lane between the first die and the second die.

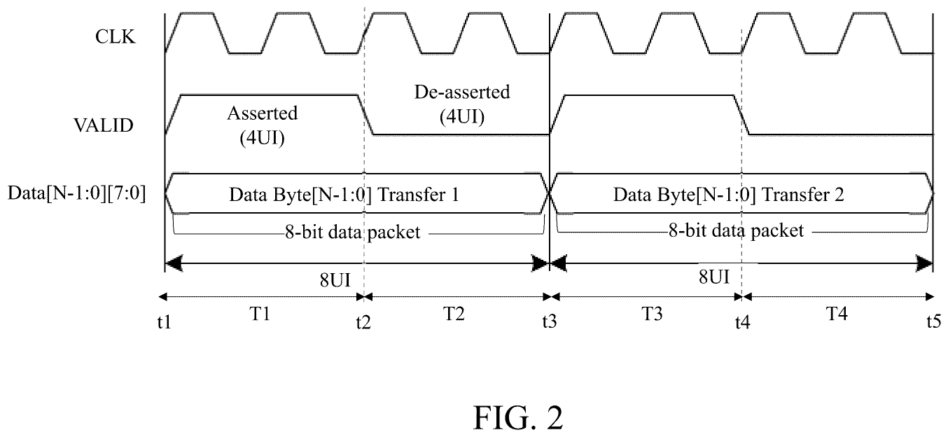

FIG. 2 is a waveform diagram illustrating a valid framing scheme in an inter-die communication protocol in accordance with some embodiments of the present disclosure.

In some embodiments, the receiver 112 shown in FIG. 1 may receive a clock signal CLK, a valid signal VALID, and a data signal Data[N-1:0] from the transmitter 104. Additionally, the data signal Data[N-1:0] may be a serial data signal, which is transmitted from the transmitter 104 to the receiver 112 using a relatively high frequency. The deserializer 1042 may be configured to receive the serial data signal via a respective input data port, and convert the received serial data signal to a parallel data signal for use by the subsequent digital circuits.

In the field of data transmission, a unit interval is the minimum time interval between condition changes of a data transmission signal, also known as the pulse time or symbol duration time. A unit interval (UI) is the time taken in a data stream by each subsequent pulse (or symbol). For brevity, the inter-die communication protocol may refer to a Universal Chiplet Interconnect Express (UCIe) 1.0 protocol or any version developed later. In the context of this patent application, a die-to-die connection refers to a linkage between any two dies, which may include a chip or a chiplet. A die is defined as any integrated circuit that is fabricated on a wafer and subsequently cut, removed, or otherwise extracted. The wafer may be composed of silicon, glass, gallium nitride, or any other material suitable for the formation of integrated circuits. Each die involved in a die-to-die connection incorporates a module. Consistent with UCIe 1.0, a module comprises a die-to-die adapter processor, PHY (physical) logic, and the PHY interface. This interface encompasses the transmitters and receivers for each line. A die may contain multiple modules, which can be connected to modules of different dies or within the same die. Although the examples provided are within the framework of UCIe 1.0, adherence to this interface specification is not mandatory. The die-to-die connections described herein may also facilitate the connection of two packages across a printed circuit board.

In some embodiments, the valid signal VALID is used to frame the transmitted data signal Data[N-1:0] using a specific pattern. For example, each clock cycle of the clock signal CLK may have two unit intervals (UIs). For each 8-bit data packet (e.g., N=8), during the first data transfer operation (e.g., Data Byte[N-1:0] Transfer 1), the valid signal VALID is asserted for the first four UIs (e.g., time period T1 from time t1 to t2), and de-asserted for the second four UIs (e.g., time period T2 from time t2 to time t3), as depicted in FIG. 2.

Additionally, if the second data transfer operation (e.g., Data Byte[N-1:0] Transfer 2) follows the first data transfer operation (e.g., Data Byte[N-1:0] Transfer 1), the valid signal VALID is asserted again for another four UIs (e.g., time period T3 from time t3 to t4), and de-asserted for subsequent four UIs (e.g., time period T4 from time t4 to time t5).

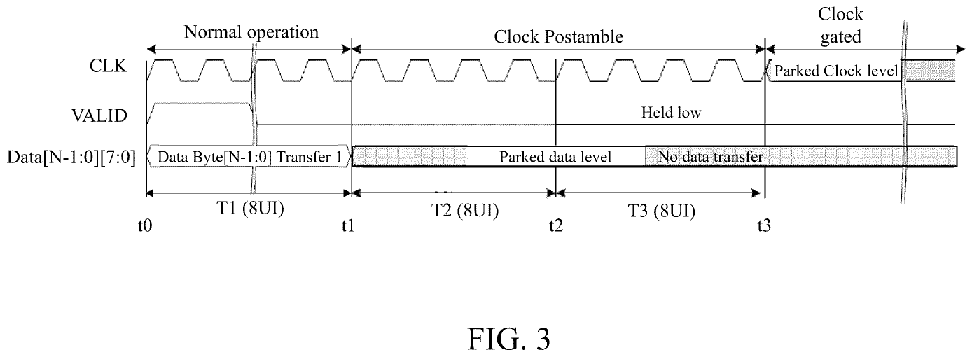

FIG. 3 is a waveform diagram illustrating a clock gating scheme in the inter-die communication protocol in accordance with some embodiments of the present disclosure.

In some embodiments, the clock signal CLK may be regarded as a forwarded clock signal. The receiver 112 gates the clock signal CLK (e.g., time t3) when the valid signal VALID is maintained at the low logic state for a fixed duration of 16 UIs (e.g., time periods T1 and T2 from time t1 to t3) after the last bit of the data signal Data[0] is transmitted (e.g., time t1). Here, the fixed duration can be referred to as a clock postamble, as depicted in FIG. 3. The valid signal VALID is asserted during the first half (e.g., 4 UIs) of time period T1, and is de-asserted during the second half (e.g., 4 UIs) of time period T2.

Additionally, the data signal [N-1][7:0] may be at a parked data level (e.g., low logic level) after the valid framing period (e.g., time period T1 from time t0 to time t1), indicating that there is no data transfer on the communication channel 108. When the clock signal CLK is gated by the receiver 112, the clock signal CLK may be set to a parked clock level (e.g., low logic level), thereby reducing power consumption of the receiver 112. In some embodiments, the receiver 112 may be in a free running clock mode defined in the UCIe 1.0 protocol, indicating that the clock signal CLK remains toggling even when the valid signal VALID is held low and there is no data transfer on the transmission interface (e.g., UCIe interface).

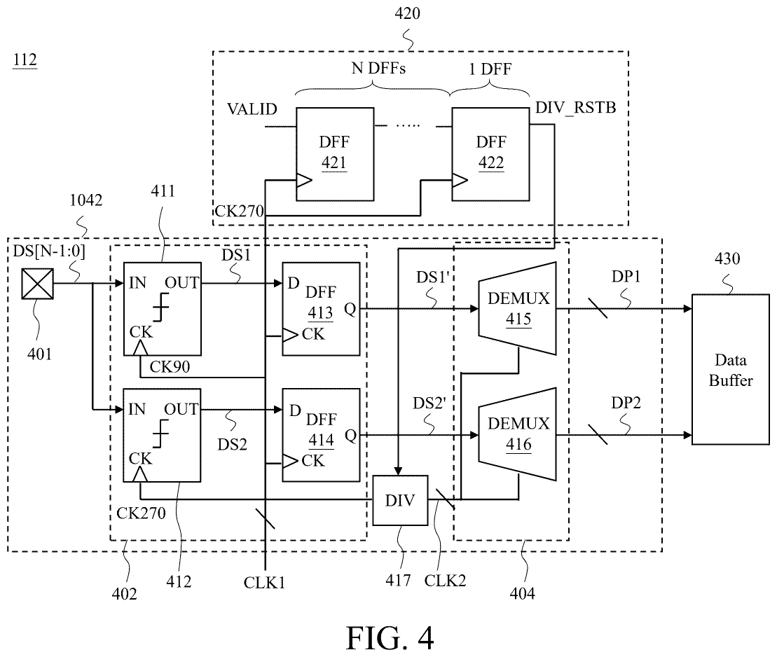

FIG. 4 is a block diagram of a receiver compatible with the first inter-die communication protocol in accordance with some embodiments of the present disclosure.

In some embodiments, the receiver 112 shown in FIG. 1 may include the deserializer 1042 and a dynamic reset generation circuit 220. The input serial data signal DS is accompanied with an input clock signal CLK (not shown in FIG. 4). The deserializer 1042 may also be regarded as a demultiplexor that is configured to convert the input serial data signal (e.g., DS[N-1:0]) with a higher frequency, which is received from a data port 401, into a parallel data signal DP (e.g., including an upper half DP1 and a lower half DP2), which is stored in a data buffer 430 for use by the subsequent digital circuits (not shown). For purposes of description, the deserializer 1042 shown in FIG. 4 may be configured to perform a 1-to-8 deserialization, indicating that an 8-bit serial data signal is converted into an 8-bit parallel data signal. Additionally, the frequency of the input serial data signal DS[N-1:0] may be 16 GHz, and thus the bandwidth of the input serial data signal DS[N-1] may be approximately 16 Gbps (e.g., one data bit is received by the data port 401 per clock cycle of the input clock signal CLK), while the output parallel data signal DP1 and DP2 may each have a bandwidth (or data rate) of approximately 2 Gbps with a second clock signal CLK2 of approximately 2 GHz. It should be noted that the ratio of deserialization and the frequencies described above are for illustrative purposes, and they can be changed according to practical needs.

In other words, the frequency fᵢₙ of the input clock signal CLK is eight times the frequency fᵢₙ₂ of the second clock signal set CLK2 (i.e., fᵢₙ₂=(⅛)fᵢₙ). Furthermore, the deserializer 1042 may receive a first clock signal set CLK1, which includes two clock signals with opposite phases, such as a 90-degree clock signal CK90 and a 270-degree clock signal CK270 (or a 0-degree clock signal CK0 and a 180-degree clock signal CK180). The frequency fᵢₙ₁ of the clock signal set CLK1, including clock signals CK90 and CK270, may be half of the frequency of input clock signal CLK, such as 4 GHz (i.e., fᵢₙ₁=(½)fᵢₙ).

In some embodiments, the deserializer 1042 may include a first stage 402, a clock divider, and a second stage 404. The first stage 402 includes data slicers 411 and 412, and D flip-flops (DFF) 413 and 414, while the second stage 404 includes demultiplexers (DEMUX) 415 and 416, as depicted in FIG. 4. The input clock terminals CK of the data slicers 411 and 412 may receive the clock signals CK90 and CK270, respectively. For example, the data slicer 411 samples the input serial data signal DS received at its input data terminal IN at the rising edge of the clock signal CK90 to output a first partial serial data signal DS1 at its output data terminal OUT, while the data slicer 412 samples the input serial data signal DS received at its input data terminal IN at the rising edge of the clock signal CK270 to output a second partial serial data signal DS2 at its output data terminal OUT. In other words, the first partial serial data signal DS1 may include even-indexed bits (e.g., DS[0], DS[2], DS[4], DS[6], and the like) of the input serial data signal DS, while the second partial serial data signal DS2 may include odd-indexed bits (e.g., DS[1], DS[3], DS[5], DS[7], and the like) of the input serial data signal DS. Alternatively, the first partial serial data signal DS1 may include even-indexed bits (e.g., DS[1], DS[3], DS[5], DS[7], and the like) of the input serial data signal DS, while the second partial serial data signal DS2 may include odd-indexed bits (e.g., DS[0], DS[2], DS[4], DS[6], and the like) of the input serial data signal DS.

In some embodiments, the input clock terminal CK of the D flip-flop 413 receives the clock signal CK90, while the input clock terminal CK of the D flip-flop 414 receives the clock signal CK270. The output data of the data slicer 411 is forwarded to the input data terminal D of the D flip-flop 413, while the output data of the data slicer 412 is forwarded to the input data terminal D of the D flip-flop 414. Accordingly, the D flip-flop 413 samples the first partial serial data signal DS1 at the rising edge of the clock signal CK90 to generate a first partial serial data signal DS1′, while the D flip-flop 414 samples the second partial serial data signal DS2 at the rising edge of the clock signal CK270 to generate a second partial serial data signal DS2′. It should be noted that the first partial serial data signal DS1′ and the second partial serial data signal DS2′ are delayed versions of the first partial serial data signal DS1 and the second partial serial data signal DS2, respectively. Additionally, the clock frequency of the clock signals CK90 and CK270 corresponding to the first partial serial data signal DS1 and the second partial serial data signal DS2 may be half the frequency of the input clock signal CLK, indicating that the bandwidth of the first partial serial data signal DS1 and the second partial serial data signal DS2 are approximately 8 Gbps.

In some embodiments, the first clock signal set is sent to the clock divider 417, which is configured to divide the clock signals CK90 and CK270 within the first clock signal set by a clock division factor M to generate the second clock signal set including divided clock signals CK2_0, CK2_90, CK2_180, and CK2_270 (not shown in FIG. 4) with phases of 0 degrees, 90 degrees, 180 degrees, and 270 degrees, respectively. For brevity, the clock division factor M used by the clock divider 417 is 4, indicating that the frequency of the clock signals CK2_0, CK2_90, CK2_180, and CK2_270 is a quarter of the frequency fᵢₙ₁ of the first clock signal set CLK1 (i.e., fᵢₙ₂=(¼)fᵢₙ₁), which is also one-eighth of the frequency fᵢₙ of the input clock signal CLK (i.e., fᵢₙ₂=(⅛)fᵢₙ). Accordingly, the demultiplexer 415 is configured to select the corresponding bits of the first partial serial data signal DS1′ at the rising edges of the clock signals CK2_0, CK2_90, CK2_180, and CK2_270 to generate the partial parallel data signal DP1 which is stored in the data buffer 430. Similarly, the demultiplexer 416 is configured to select the corresponding bits of the first partial serial data signal DS2′ at the rising edges of the clock signals CK2_0, CK2_90, CK2_180, and CK2_270 to generate the partial parallel data signal DP2 which is stored in the data buffer 430. The first partial parallel data signal DP1 and the second partial parallel data signal DP2 stored in the data buffer 430 can constitute the parallel data signal DP, which is provided to the subsequent digital circuits.

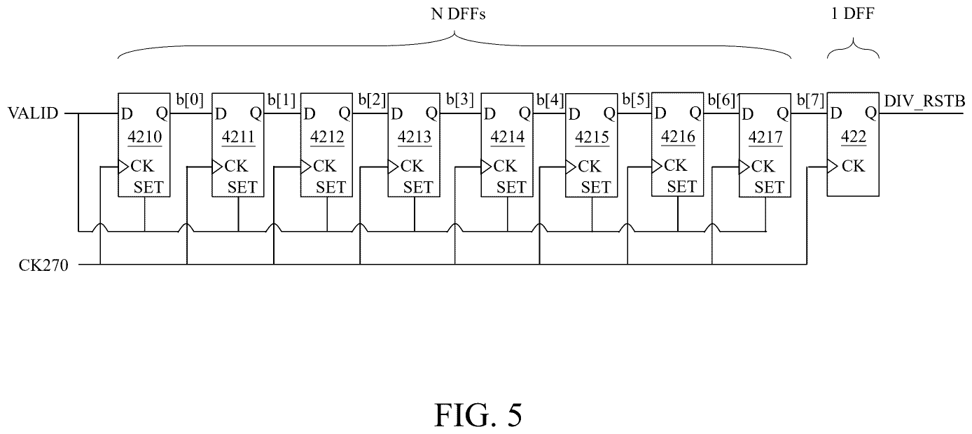

In some embodiments, the dynamic reset generation circuit 420 is configured to dynamically generate a reset signal DIV_RSTB of the clock divider 417 in response to the valid signal VALID and the clock signal CLK270. As a result, the generated reset signal DIV_RSTB can serve as a universal reset signal for the clock divider 417 across arbitrary demultiplexing ratios supported by the UCIe protocol. Additionally, the timings for the assertion and de-assertion of the reset signal DIV_RSTB are generated dynamically, enabling the receiver 112 to process data deserialization correctly. Moreover, the reset signal DIV_RSTB generated by the dynamic reset generation circuit 420 can be asserted during periods of no data transmission, thereby turning off the clock divider 417 to achieve power savings. The details of the dynamic reset generation circuit 420 are described with reference to the embodiments of FIGS. 5 to 8.

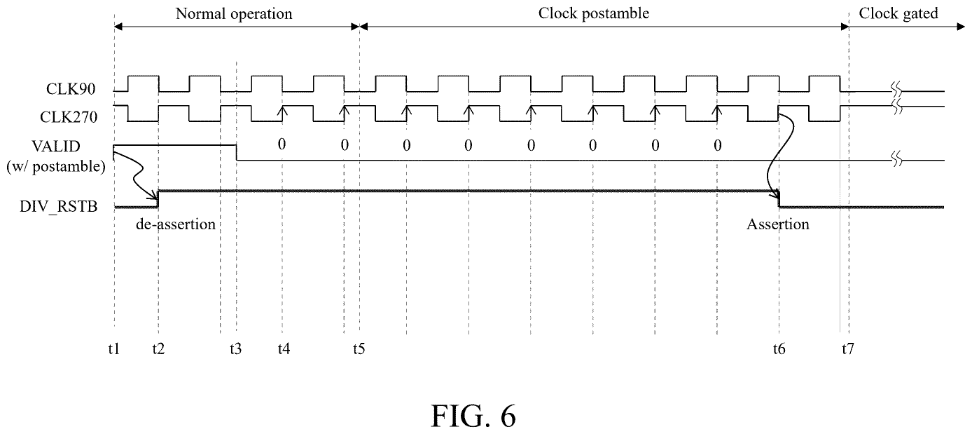

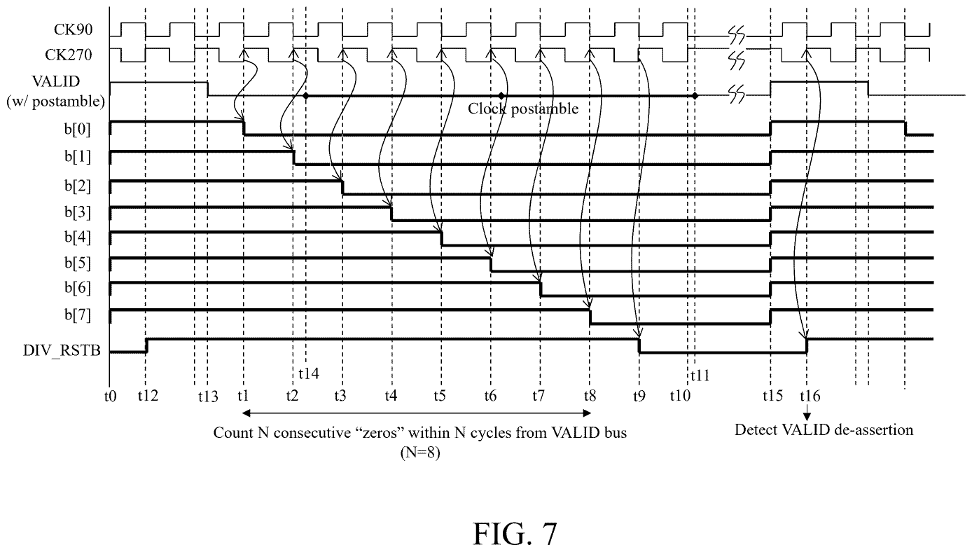

FIG. 5 is a detailed block diagram of the dynamic reset generation circuit 420 in accordance with the embodiment of FIG. 4. FIG. 6 is a waveform diagram of various signal within the receiver in accordance with the embodiment of FIG. 5. FIG. 7 is another waveform diagram of various signal within the receiver in accordance with the embodiment of FIG. 5.

In some embodiments, the dynamic reset generation circuit 420 includes a plurality of D flip-flops 421 of a first type (e.g., N DFFs 421), and a D flip-flop 422 of a second type, as depicted in FIG. 5. The D flip-flops 421 of the first type may refer to D flip-flops with a set function (or a reset function). When the set signal received at the set terminal SET of a D flip-flop 421 is in a high logic state (e.g., “1”), the output data at the output terminal Q of the D flip-flop 421 is set to the high logic state (e.g., “1”) regardless of the input data received at its input terminal D and the logic state of the input clock signal CK270 received at its input clock terminal CK. When the set signal received at the set terminal SET of a D flip-flop 421 is in a low logic state (e.g., “0”), the D flip-flop is in a normal operation mode, which samples the input data at the input data terminal D at the rising edge of the input clock signal CK270 received at its input clock terminal CK to generate the output data at its output terminal Q. The D flip-flop 422 of the second type may refer to a D flip-flop without a set function, and it is configured to sample the input data at the input data terminal D at the rising edge of the input clock signal CK270 received at its input clock terminal CK to generate the output data at its output terminal Q. In some other embodiments, the D flip-flop 422 is configured to sample the input data at the input data terminal D at the rising edge of the input clock signal CK90 received at its input clock terminal CK to generate the output data at its output terminal Q.

Alternatively, when the D flip-flops 421 of the first type refer to D flip-flops with the reset function, an inverted version of the valid signal VALID (e.g., VALID′) is provided to the reset terminal of each D flip-flops 421.

In some embodiments, the reset signal DIV_RSTB generated by the dynamic reset generation circuit 420 is a low-active signal, indicating that the reset signal DIV_RSTB is effective in a low logic state. For example, referring to FIG. 6, during the effective valid frame (e.g., the time period from time t1 to time t5), the reset signal DIV_RSTB generated by the dynamic reset generation circuit 420 is asserted in response to an effective valid frame being detected (e.g., 8′b11110000 with reference to the input clock signal CLK). For example, the reset signal DIV_RSTB is initially asserted (e.g., “0”). At time t1, the valid signal VALID, which is a high-active signal, is asserted at the rising edge of the input clock signal CLK, indicating a start of an effective valid frame. Subsequently, at time t2, the dynamic reset generation circuit 420 de-asserts the reset signal DIV_RSTB (e.g., “1”) at the following rising edge of the clock signal CK270, enabling the clock divider 417 to divide the first clock signal set CLK1 by the clock division factor M to generate the second clock signal set CLK2. Additionally, during the clock postamble period (e.g., the period from time t5 to time t7), the dynamic reset generation circuit 420 asserts the reset signal DIV_RSTB (e.g., “0”) when N consecutive zeros are received in N clock cycles of the clock signal CK270, disabling the clock divider 417 to achieve power savings. For purposes of description, N equals to 8 in the embodiments of FIGS. 5 to 8. It should be noted that the value of N can be adjusted according to practical needs.

More specifically, the dynamic reset generation circuit 420 includes N+1 D flip-flops, with N DFFs 421 of the first type and one DFF 422 of the second type arranged in a cascaded architecture (e.g., connected in series), as depicted in FIG. 5. For brevity, N equal to 8, indicating that the DFFs 421 shown in FIG. 4 include DFFs 4210 to 4217 shown in FIG. 5. The N+1 D flip-flops within the dynamic reset generation circuit 420 are used to de-assert the reset signal DIV_RSTB when the effective valid frame is detected.

Referring to FIG. 7, the waveforms of the output data signals b[0] to b[7] of the D flip-flops 4210 to 4217 are illustrated. For example, the reset signal DIV_RSTB is initially asserted (e.g., “0”). At time t0, in response to assertion of the valid signal VALID, the output data signals b[0] to b[7] of the D flip-flops 4210 to 4217 are set to the high logic state (e.g., “1”). The output data signals b[0] to b[7] are maintained at the high logic state when the valid signal VALID is asserted (e.g., the time period from time t0 to time t12). Additionally, at time t12, the reset signal DIV_RSTB is de-asserted at the following rising edge of the clock signal CK270 after time t0, enabling the clock divider 417 to divide the first clock signal set CLK1 by a clock division factor M to generate the second clock signal set CLK2.

At time t12, the valid signal VALID is de-asserted (e.g., “0”), and it is maintained at the low logic state (e.g., “0”) during the period from time t13 to time t14. From time t14, the valid signal is maintained at the low logic state (e.g., “0”) during the clock postamble period from time t14 to time t11. Additionally, the input clock signal CLK is gated in response to completion of the clock postamble at time 11, disabling the input clock signal CLK.

Additionally, at time t1, the D flip-flop 4210 samples the valid signal VALID at the following rising edge of the clock signal CK270 after time t12, thereby changing its output data signal b[0] to the low logic state (e.g., “0”). The output data signal b[0] in the low logic state (e.g., “0”) at time t1 can be considered as the first zero among the sequence of N consecutive zeroes. It should be noted that the output data signals b[1] to b[7] are still maintained at the high logic state (e.g. “1”) at time t1 since the remaining D flip-flops 4211 to 4217 sample the output data signals b[0] to b[6], which are in the high logic state (e.g., “1”) at time t1.

At time t2, the D-flip flop 4211 samples the output data signal b[0] generated by the D flip-flop 4210, thereby changing its output data signal b[1] to the low logic state (e.g., “0”). The output data signal b[0] in the low logic state (e.g., “0”) at time t1 can be considered as the second zero among the sequence of N consecutive zeroes. It should be noted that the output data signals b[2] to b[7] are still maintained at the high logic state (e.g. “1”) at time t1 since the remaining D flip-flops 4212 to 4217 sample the output data signals b[1] to b[6], which are in the high logic state (e.g., “1”) at time t2. The waveforms of the output data signal b[3] to b[7] can be derived in a similar manner.

As depicted in FIG. 7, the dynamic reset generation circuit 420 counts eight consecutive zeroes at time t8. Subsequently, the D flip-flop 422 samples the output data signal b[7], which is in the low logic state (e.g., “0”), at time t9, thereby asserting the reset signal DIV_RSTB (e.g., “0”). Accordingly, at time t10, which is one cycle of the forward clock signals CK90 and CK270 after time t9, the forward clock signals CK90 and CK270 are maintained at the low logic state and the high logic state during the clock gated period, as depicted in FIG. 7.

Additionally, at time t15, the valid signal VALID is asserted again, and receiver 112 disables the clock gating of the input clock signal CLK and the forwarded clock signals CK90 and CK270. Meanwhile, all the output data signal b[0] to b[7] of the D flip-flops 4210 to 4217 are set to the high logic state (e.g., “1”) in response to the assertion of the valid signal VALID at time 15. Subsequently, the D flip-flop 422 outputs the reset signal DIV_RSTB in the high logic state at time t16, indicating the de-assertion of the reset signal DIV_RSTB. Accordingly, at time 16, the clock divider 417 is activated again to divide the first clock signal set CLK1 by a clock division factor M to generate the second clock signal set CLK2 in response to the de-assertion of the reset signal DIV_RSTB.

Specifically, in response to the de-assertion of the reset signal DIV_RSTB (e.g., “1”), the reset signal DIV_RSTB is kept de-asserted when the valid frame (e.g., 8′b11110000 with reference to the input clock signal CLK) is repeated periodically. Additionally, in response to the assertion of the reset signal DIV_RSTB (e.g., “0”), the reset signal DIV_RSTB is kept asserted until a new valid frame (e.g., 8′b11110000 with reference to the input clock signal CLK) is resumed.

In some embodiments, the value of the number N is adjustable according to the design specification of the receiver 112, indicating that the number of D flip-flops 421 and the number of consecutive zeros to be detected are adjusted correspondingly. For example, the number N may be an integer between 2 and 10. The receiver 112 may save more power with a smaller number of N, and gain more demultiplexing timing margin with a larger number of N. For example, when the number N equals 2, the dynamic reset generation circuit 420 does not need to wait for the end of the clock postamble, and it can assert the reset signal DIV_RSTB after (2+1) rising edges of the clock signal CK270. Accordingly, the clock divider 417 can be deactivated prior to the end of the clock postamble, thereby achieving more power saving. When the number N equals 8, and it can assert the reset signal DIV_RSTB after (8+1) rising edges of the clock signal CK270, allowing the dynamic reset generation circuit 420 to have a larger demultiplexing timing margin.

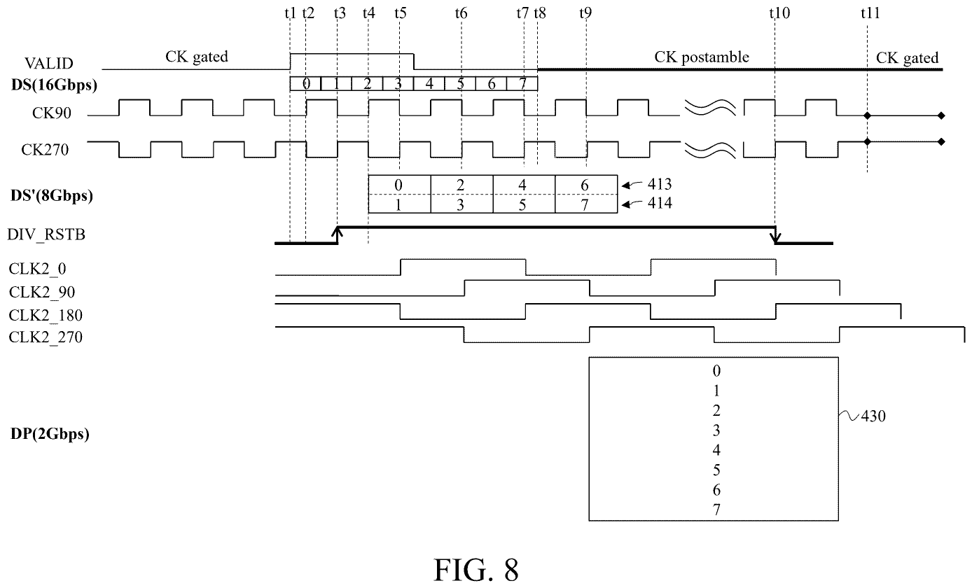

FIG. 8 is a diagram illustrating waveforms of various signal and the statuses of data buffers within the receiver in accordance with the embodiment of FIG. 5. Please refer to both FIG. 4 and FIG. 8 simultaneously.

For purposes of description, the input clock signal CLK, which has a frequency of 16 GHz, is omitted from FIG. 8. It should be noted that the valid signal VALID and the input data signal DS are accompanied with the input clock signal CLK. Referring FIG. 8, at time t1, the valid signal VALID is asserted (e.g., “1”), indicating that a valid frame starts (e.g., 8′b11110000 with reference to the input clock signal CLK at 16 GHz). Thus, the input serial data signal DS are valid during the valid frame. At time t2, the data slicer 411 samples the input serial data signal DS (e.g., the least significant bit DS[0]) at the rising edge of the clock signal CK90, which is stored in the D flip-flop 413 at the next rising edge of the clock signal CK90 at time t4. At time t3, the data slicer 412 samples the input serial data signal DS (e.g., DS[1]) at the rising edge of the clock signal CK270, which is stored in the D flip-flop 414 at the next rising edge of the clock signal CK270 at time t5. The following data bits of the input serial data signal DS can be sampled by the data slicers 411 and 412, and stored in the D flip-flops 413 and 414 in a similar manner.

Additionally, the data DS1 stored in the D flip-flop 413 is sampled by the clock signals CLK2_0, CLK2_90, CLK_180, and CLK2_270 within the second clock signal set CLK2 at their rising edges, such as times t5, t6, t7, and t9. For example, at time t5, the data signals DS1′ (e.g., DS[0]) and DS2′ (e.g., DS[1]) respectively stored in the D flip-flops 413 and 414 are sampled at the rising edge of the clock signal CLK2_0, and stored in the data buffer 430 through the demultiplexer 415. Subsequently, at time t6, the data signals DS1′ (e.g., DS[2]) and DS2′ (e.g., DS[3]) respectively stored in the D flip-flops 413 and 414 are sampled at the rising edge of the clock signal CLK2_90, and stored in the data buffer 430 through the demultiplexer 415. Similarly, at time t7, the data signals DS1′ (e.g., DS[4]) and DS2′ (e.g., DS[5]) respectively stored in the D flip-flops 413 and 414 are sampled at the rising edge of the clock signal CLK2_180, and stored in the data buffer 430 through the demultiplexer 415. Lastly, at time t9, the data signals DS1′ (e.g., DS[6]) and DS2′ (e.g., DS[7]) respectively stored in the D flip-flops 413 and 414 are sampled at the rising edge of the clock signal CLK2_270, and stored in the data buffer 430 through the demultiplexer 415. Accordingly, all data bits DS[0] to DS[7] of the input serial data signal DS are stored in the data buffer 430 at time t9.

It should be noted that the de-assertion of the reset signal DIV_RSTB is generated based on the valid frame. Additionally, the timing for the assertion of the reset signal DIV_RSTB can be determined by the number of D flip-flops 421 and 422 within the dynamic reset generation circuit 420. Accordingly, regardless of whether a QDRTM (quad data rate) or DDR (double data rate) application, or an application with a higher data rate using higher demultiplexing ratios to achieve higher throughput, is used, the receiver 112 is capable of generating appropriate timings for asserting and de-asserting the reset signal DIV_RSTB for the clock divider 417, thereby obtaining correct clock phases of the clock divider 417 for demultiplexing during the clock gated period in the clock gating mode. Therefore, the proposed method for generating a dynamic reset signal can be used to address the UCIe demultiplexing data traffic in real time. Additionally, the dynamic reset generation circuit 420 can assert the reset signal to gate the clock signals generated by the clock divider 417, thereby achieving power savings in the clock gating mode.

It should be further noted that the reset signal for the clock divider may be an asynchronous reset signal received from an external circuit or external test equipment, and the timing of de-assertion of the reset signal will determine whether the demultiplexing results of the input serial data signal are correct. For example, when the asynchronous reset signal is de-asserted approximately 0.5 UI before the assertion of the valid signal, two invalid bits may be demultiplexed and fetched. When the asynchronous reset signal is de-asserted approximately 2.5 UI before the assertion of the valid signal, four invalid bits may be demultiplexed and fetched. When the asynchronous reset signal is de-asserted approximately 4.5 UI before the assertion of the valid signal, six invalid bits may be demultiplexed and fetched. The proposed method for dynamically generating the reset signal for the clock divider 417 can be used to address the aforementioned issues of these approaches.

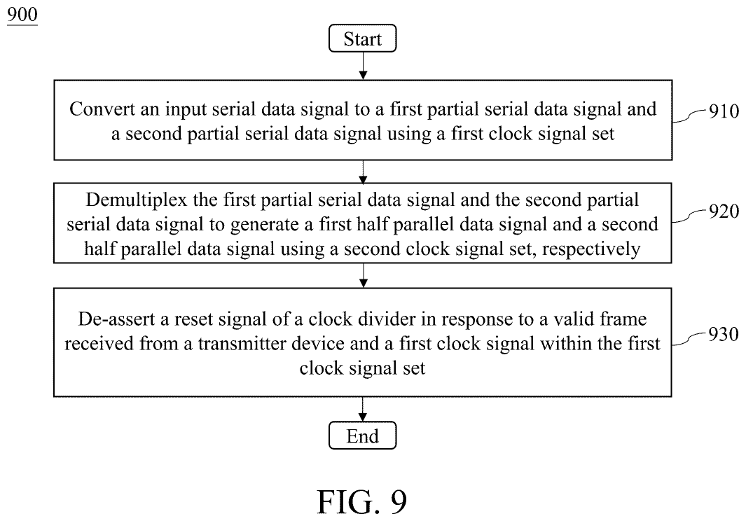

FIG. 9 is a flowchart of a method for operating a receiver device in accordance with some embodiments of the present disclosure. Please refer to FIG. 4, FIG. 5, and FIG. 9 simultaneously. The flow 900 includes operation 910 to 930.

At operation 910, convert an input serial data signal to a first partial serial data signal and a second partial serial data signal using a first clock signal set. In some embodiments, the first stage 402 of the receiver 112 is configured to convert the input serial data signal DS to a first partial serial data signal DS1′ and a second partial serial data signal DS2′. The first partial serial data signal DS1′ may include even-indexed bits of the input serial data signal DS, while the second partial serial data signal DS2′ may include odd-indexed bits of the input serial data signal DS.

At operation 920, demultiplex the first partial serial data signal and the second partial serial data signal to generate a first half parallel data signal and a second half parallel data signal using a second clock signal set, respectively. In some embodiments, the clock divider 417 is configured to divide the first clock signal set CLK1 by a clock division ratio (e.g., 4) to generate the second clock signal set CLK2. Additionally, the second clock signal set CLK2 may include four clock signals in quadrature phases of 0 degrees, 90 degrees, 180 degrees, and 270 degrees. In response to assertion of the reset signal DIV_RSTB, the clock divider 417 is disabled. In response to de-assertion of the reset signal DIV_RSTB, the clock divider 417 is enabled to divide the first clock signal set CLK1 by the clock division ratio to generate the second clock signal set CLK2.

At operation 930, assert a reset signal of a clock divider in response to a valid frame received from a transmitter device and a first clock signal within the first clock signal set. In some embodiments, the valid frame comprises an assertion period of a valid signal VALID in the high logic state (e.g., “1”) and a de-assertion period of the valid signal VALID in the low logic state (e.g., “0”).

An aspect of the present disclosure provides a receiver device, which includes a deserializer and a dynamic reset generation circuit. The deserializer includes a first stage, a clock divider, and a second stage. The first stage is configured to convert an input serial data signal to a first partial serial data signal and a second partial serial data signal using a first clock signal set. The clock divider is configured to divide the first clock signal set by a clock division ratio to generate a second clock signal set. The second stage is configured to demultiplex the first and second partial serial data signals to generate a first half parallel data signal and a second half parallel data signal using the second clock signal set, respectively. The dynamic reset generation circuit asserts a reset signal of the clock divider in response to a valid frame and a first clock signal within the first clock signal set.

Another aspect of the present disclosure provides a receiver device, which includes a deserializer and a dynamic reset generation circuit. The deserializer is configured to convert an input serial data signal into a parallel data signal using a predetermined demultiplexing ratio. The input serial data signal is with reference to an input clock signal and a valid signal received from a transmitter device. The dynamic reset generation circuit is configured to, in response to assertion of the valid signal, de-assert a reset signal for use by the deserializer at a rising edge of a first clock signal subsequent to the assertion of the valid signal. A frequency of the first clock signal is lower than that of the input clock signal.

Yet another aspect of the present disclosure provides a method. The method includes the following steps: converting an input serial data signal to a first partial serial data signal and a second partial serial data signal using a first clock signal set; demultiplexing the first partial serial data signal and the second partial serial data signal to generate a first half parallel data signal and a second half parallel data signal using a second clock signal set, respectively; and asserting a reset signal of the clock divider in response to a valid frame received from a transmitter device and a first clock signal within the first clock signal set.

The methods and features of the present disclosure have been sufficiently described in the provided examples and descriptions. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, can be utilized according to the present disclosure.

Accordingly, the appended claims are intended to include within their scope processes, machines, manufacture, compositions of matter, means, methods or steps. In addition, each claim constitutes a separate embodiment, and the combination of various claims and embodiments are within the scope of the present disclosure.

What is claimed is:

1. A receiver device, comprising:
a deserializer, comprising:
a first stage, configured to convert an input serial data signal to a first partial serial data signal and a second partial serial data signal using a first clock signal set;
a clock divider, configured to divide the first clock signal set by a clock division ratio to generate a second clock signal set; and
a second stage, configured to demultiplex the first partial serial data signal and the second partial serial data signal to generate a first half parallel data signal and a second half parallel data signal using the second clock signal set, respectively; and
a dynamic reset generation circuit, configured to de-assert a reset signal of the clock divider in response to a valid frame received from a transmitter device and a first clock signal within the first clock signal set.

2. The receiver device of claim 1, wherein the receiver device receives the input serial data signal accompanied with a valid signal and an input clock signal, which has a frequency substantially equal to that of the first clock signal set.

3. The receiver device of claim 1, wherein the first clock signal set comprises the first clock signal having a first phase and a second clock signal having a second phase, and the second phase is opposite to the first phase.

4. The receiver device of claim 3, wherein the first partial serial data signal comprises even-indexed bits of the input serial data signal, and the second partial serial data signal comprises odd-indexed bits of the input serial data signal.

5. The receiver device of claim 4, wherein the first stage comprises:
a first slicer, configured to sample the input serial data signal at a rising edge of the first clock signal to generate a first output data signal during the valid frame;
a second slicer, configured to sample the input serial data signal at a rising edge of the second clock signal to generate a second output data signal during the valid frame;
a first D flip-flop, configured to sample the first output data signal at the rising edge of the first clock signal during the valid frame; and
a second D flip-flop, configured to sample the second output data signal at the rising edge of the second clock signal during the valid frame.

6. The receiver device of claim 5, wherein the second clock signal set comprises four clock signals in quadrature phases of 0 degrees, 90 degrees, 180 degrees, and 270 degrees.

7. The receiver device of claim 6, wherein the second stage comprises:
a first demultiplexer, configured to demultiplex the first partial serial data signal using the four clock signals within the second clock signal set to generate the first half parallel data signal; and
a second demultiplexer, configured to demultiplex the second partial serial data signal using the four clock signals within the second clock signal set to generate the second half parallel data signal.

8. The receiver device of claim 7, wherein the first half parallel data signal and the second half parallel data signal are stored in a data buffer to serve as a parallel data signal.

9. The receiver device of claim 3, wherein the dynamic reset generation circuit comprises N first D flip-flops of a first type, and a second D flip-flop of a second type which are connected in a cascaded architecture, and N is a positive integer greater than or equal to 2.

10. The receiver device of claim 9, wherein each of the first D flip-flops of the first type comprises a set terminal to provide a set function.

11. The receiver device of claim 10, wherein:
the valid frame comprises an assertion period of a valid signal in a high logic state and a de-assertion period of the valid signal in a low logic state; and
the assertion period and the de-assertion period are equal to a duration of two clock cycles of the first clock signal set.

12. The receiver device of claim 11, wherein:
the valid signal is provided to the set terminal of each first D flip-flop within the dynamic reset generation circuit; and
the second clock signal is provided to an input clock terminal of each first D flip-flop and the second D flip-flop.

13. The receiver device of claim 12, wherein:
in response to assertion of the valid signal, each first D flip-flop sets its output data signal to the high logic state; and
the reset signal generated by the second D flip-flop is de-asserted by the dynamic reset generation circuit at a rising edge of the second clock signal following the assertion of the valid signal.

14. The receiver device of claim 13, wherein in response to de-assertion of the valid signal, the reset signal generated by the second D flip-flop is asserted after N consecutive zeros subsequent to the de-assertion of the valid signal are detected.

15. A receiver device, comprising:
a deserializer, configured to convert an input serial data signal into a parallel data signal using a predetermined demultiplexing ratio, wherein the input serial data signal is with reference to an input clock signal and a valid signal received from a transmitter device; and
a dynamic reset generation circuit, configured to, in response to assertion of the valid signal, de-assert a reset signal for use by the deserializer at a rising edge of a first clock signal subsequent to the assertion of the valid signal,
wherein a frequency of the first clock signal is substantially equal to that of the input clock signal.

16. The receiver device of claim 15, wherein the dynamic reset generation circuit comprises a D flip-flop chain, which comprises N first D flip-flop of a first type, and a second D flip-flop, and N is a positive integer greater than or equal to 2.

17. The receiver device of claim 16, wherein:
in response to assertion of the valid signal, each first D flip-flop sets its output data signal to a high logic state;
the reset signal generated by the second D flip-flop is de-asserted by the dynamic reset generation circuit at a rising edge of a second clock signal following the assertion of the valid signal;
a first phase of the first clock signal is opposite to a second phase of the second clock signal; and
in response to de-assertion of the valid signal, the reset signal generated by the second D flip-flop is asserted after N consecutive zeros subsequent to the de-assertion of the valid signal are detected.

18. A method, comprising:
converting an input serial data signal to a first partial serial data signal and a second partial serial data signal using a first clock signal set;
demultiplexing the first partial serial data signal and the second partial serial data signal to generate a first half parallel data signal and a second half parallel data signal using a second clock signal set, respectively; and
de-asserting a reset signal of a clock divider in response to a valid frame received from a transmitter device and a first clock signal within the first clock signal set.

19. The method of claim 18, further comprising:
dividing, by the clock divider, the first clock signal set by a clock division ratio to generate the second clock signal set.

20. The method of claim 19, wherein:
the first clock signal set comprises the first clock signal having a first phase and a second clock signal having a second phase, and the second phase is opposite to the first phase; and
the second clock signal set comprises four clock signals in quadrature phases of 0 degrees, 90 degrees, 180 degrees, and 270 degrees.
